(19) United States
(12) Patent Application Publication
(10) Pub. No.: US 2008/0080365 A1
(43) Pub. Date: Apr. 3, 2008

(54) Wireless Access Point Failover System and Method

(76) Inventor: Ranjith Thomas Mahinda Weeresinghe, Allen, TX (US)

Correspondence Address: CONLEY ROSE, P.C., 5601 GRANITE PARKWAY, SUITE 750, PLANO, TX, 75024, US

(21) Appl. No.: 11/691,234

(22) Filed: Mar. 26, 2007

Related U.S. Application Data
(60) Provisional application No. 60/827,314, filed on Sep. 28, 2006.

(51) Int. Cl. G01R 31/08

(52) U.S. Cl. 370/216

(57) ABSTRACT

A system for wireless access point failover is provided. The system includes a primary security gateway at a first site, a backup security gateway at the first site, a call manager at the first site, an alternative security gateway at a second site, a mobile device, and a wireless access point for the mobile device. The wireless access point attempts to connect to the backup security gateway at the first site in response to determining that the primary security gateway at the first site is not operational. The wireless access point also connects to the alternative security gateway at the second site in response to failing to connect to the backup security gateway. Furthermore, the wireless access point connects to the call manager via the alternative security gateway.

### CROSS-REFERENCE TO RELATED APPLICATIONS

This application claims priority to U.S. Provisional Patent Application No. 60/827,314, entitled “Residential Wireless Points Failover After Geographic Redundancy”, filed on Sep. 28, 2006, by Ranjith Weeresinghe, which is incorporated herein by reference for all purposes.

### STATEMENT REGARDING FEDERALLY SPONSORED RESEARCH OR DEVELOPMENT

Not applicable.

### REFERENCE TO A MICROFICHE APPENDIX

Not applicable.

### BACKGROUND

Wireless networks allow users mobility, freeing individuals from the restrictions of using a communication device cabled to a physical connection. A wireless access point (WAP) is a device that connects wireless communication devices together to form a wireless network. The WAP usually connects to a wired network and can relay data between wireless mobile devices and wired devices, but can also communicate with or access another WAP. A WAP can also be part of a larger network serving more users in an area.

Many wired networks base security on physical access control, trusting all users on a local network. However, if wireless access points are connected to the network, anyone on the street or in the neighboring office can connect to the wired network. Therefore, wireless access points access the wired network through a security gateway, which serves as an entry point for wireless access points to the wired network.

A WAP connection to the network is dependent upon the proper functioning of the security gateway. Wired networks often employ geographic redundancy to address dependency concerns, such as switching over to a backup security gateway when the primary security gateway is not operational, a failover condition. “Operational” is defined as a state wherein a component is processing normally, whereas “failed” or “not operational” is a state wherein the component is not processing or not processing normally.

### SUMMARY

In one embodiment, a system for wireless access point failover is provided. The system includes a primary security gateway at a first site, a backup security gateway at the first site, a call manager at the first site, an alternative security gateway at a second site, a mobile device; and a wireless access point for the mobile device. The wireless access point attempts to connect to the backup security gateway at the first site in response to determining that the primary security gateway at the first site is not operational. The wireless access point connects to the alternative security gateway at the second site in response to failing to connect to the backup security gateway. The wireless access point connects to the call manager via the alternative security gateway.

In another embodiment, a method for wireless access point failover is provided. A connection to a backup security gateway at a first site is attempted in response to determining that a primary security gateway at the first site is not operational. A connection is made to an alternative security gateway at a second site in response to failing to connect to the backup security gateway at the first site. A connection is made to a call manager at the first site via the alternative security gateway at the second site.

In yet another embodiment, a system for wireless access point failover is provided. The system includes a call manager at a first site, a primary security gateway at the first site, an alternative security gateway at a second site, an alternative call manager at the second site, a mobile device, and a wireless access point for the mobile device. The wireless access point connects to the alternative security gateway at the second site via the primary security gateway at the first site in response to determining that the call manager at the first site is not operational. The wireless access point connects to the alternative call manager at the second site via the alternative security gateway at the second site and via the primary security gateway at the first site.

These and other features will be more clearly understood from the following detailed description taken in conjunction with the accompanying drawings and claims.

### BRIEF DESCRIPTION OF THE DRAWINGS

For a more complete understanding of this disclosure, reference is now made to the following brief description, taken in connection with the accompanying drawings and detailed description, wherein like reference numerals represent like parts.

FIG. 1 shows a system for wireless access point failover according to an embodiment of the present disclosure.

FIG. 2 shows a flow chart of a method for wireless access point failover according to an embodiment of the present disclosure.

FIG. 3 shows a flow chart of another method for wireless access point failover according to an embodiment of the present disclosure.

FIG. 4 shows an illustrative wireless communications system.

FIG. 5 shows a block diagram of an illustrative mobile device.

FIG. 6 shows a diagram of an illustrative software configuration for a mobile device.

FIG. 7 illustrates an exemplary general-purpose computer system suitable for implementing the several embodiments of the disclosure.

### DETAILED DESCRIPTION OF THE PREFERRED EMBODIMENTS

It should be understood at the outset that although an illustrative implementation of one or more embodiments are provided below, the disclosed systems and/or methods may be implemented using any number of techniques, whether currently known or in existence. The disclosure should in no way be limited to the illustrative implementations, drawings, and techniques illustrated below, including the exemplary designs and implementations illustrated and described herein, but may be modified within the scope of the appended claims along with their full scope of equivalents.

Many mobile devices, such as dual mode handsets and portable computers, can use a wireless access point to make audio calls. A security gateway enables routing of such calls to a call manager that manages wireless calls. Mobile devices can make calls via a wireless access point instead of directly accessing a wireless service provider network. For example, instead of directly accessing a wireless service provider network for a mobile phone, the mobile phone may make a call via a wireless access point because the wireless service provider network may have limited signal strength based on nearby obstructions, because other electronic devices might actively interfere with the signal by broadcasting on the same frequency, and because of the type of antenna, the current weather, the operating radio frequency, or the power output of the mobile device. Making calls via a wireless access point is dependent upon the proper functioning of both the security gateway and the call manager.

Methods and systems for wireless access point failover are provided. If a wireless access point determines that both a primary security gateway and a backup security gateway at a site are not operational, according to the present disclosure the wireless access point connects to an alternative security gateway at an alternative site. Using the alternative security gateway, the wireless access point connects to the call manager.

In some embodiments, if a device manager determines that either the primary security gateway or the backup security gateway that failed is now operational, the device manager may request the wireless access point connected to the alternative security gateway to connect back to the original security gateway. The wireless access point may wait until it is idle, and then the wireless access point may connect to the security gateway that is back in operation. If the wireless access point is not idle, the wireless access point may wait until it is idle to connect back to the security gateway. By re-connecting when the wireless access points are idle, the security gateway gradually reassumes its original load when it becomes operational. This reduces the likelihood that the security gateway will fail again due to suddenly reassuming a large traffic load.

In some embodiments, if a wireless access point determines that a call manager is not operational, the wireless access point connects to an alternative security gateway at an alternative site via a primary security gateway. The wireless access point connects to an alternative call manager at the alternative site via the alternative security gateway.

In some embodiments, if a device manager determines that the call manager that failed is now operational, the device manager may request the wireless access point connected to the alternative call manager to connect to the original call manager. The wireless access point may wait until it is idle before connecting back to the call manager. If the wireless access point is not idle, the wireless access point may wait until it is idle to connect to the original call manager. By re-connecting only wireless access points that are idle, the call manager gradually reassumes its original load as it comes back on line. This reduces the likelihood that the call manager will fail again due to suddenly reassuming a large traffic load.

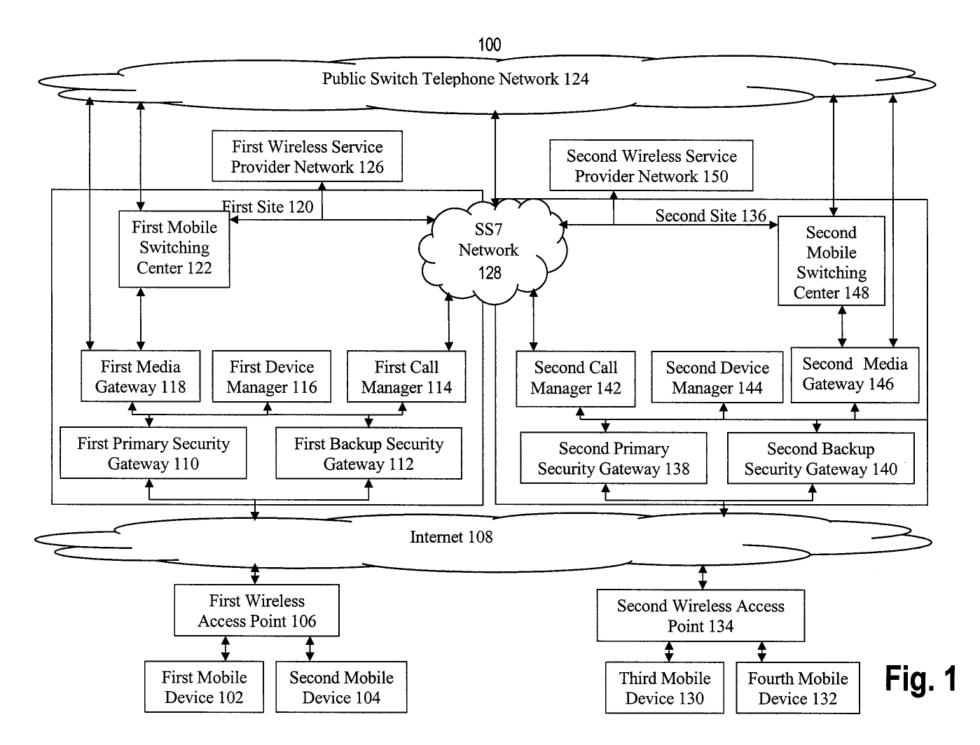

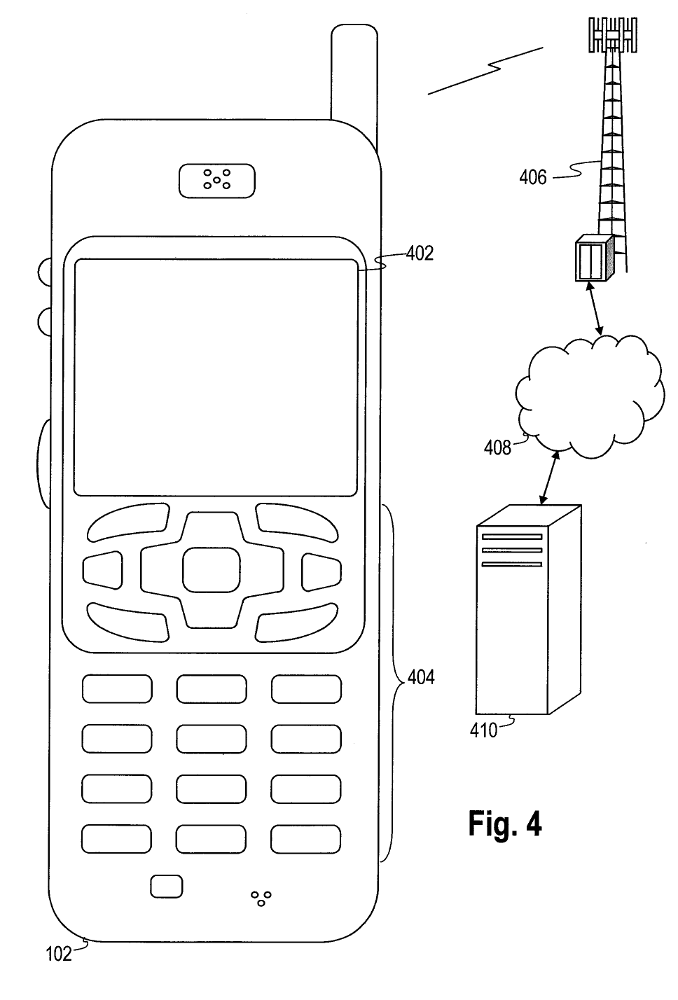

FIG. 1 depicts a system 100 for wireless access point failover according to an embodiment of the present disclosure. The system 100 includes a first mobile device 102 a second mobile device 104. The mobile devices in FIG. 1 may be dual mode handsets, portable computers, or other devices such as those described in more detail below with reference to FIGS. 4-7. The first mobile device 102 and the second mobile device 104 can communicate through a wireless access point, such as a first wireless access point 106, to access a network, such as an internet 108. The first wireless access point 106 can be an access point base station, a Pico cell, a residential wireless access point, or a similar communication device. The first wireless access point 106 may access the internet 108 through a wired cable, optical, wireless, or other communication means well known in the art. The first wireless access point 106 can connect to either a first primary security gateway 110 or a first backup security gateway 112. Either the first primary security gateway 110 or the first backup security gateway 112 can enable the first wireless access point 106 to connect to a first call manager 114.

The first call manager 114 communicates with a first device manager 116, which initially configures the first call manager 114 to communicate with wireless access points in a specified geographic region. The first device manager 116 also monitors the first wireless access point 106 and any other wireless access points that are configured to communicate with the first call manager 114.

A first media gateway 118 is a converter used by a packet-based network, such as the internet 108 to promote communication between circuit-based and packet-based networks and devices. The system 100 shows only one media gateway and one mobile switching center at a first site 120 for the purposes of an illustrative example, but the system 100 may include any number of media gateways and mobile switching centers at the first site 120. The first media gateway 118 connects the first wireless access point 106 to a first mobile switching center 122. The mobile switching center 122 carries out switching functions and manages the communications between mobile devices and a public switched telephone network (PSTN) 124. The mobile switching center 122 may be owned and deployed by a wireless service provider network, such as a first wireless service provider network 126. The mobile switching center 122 allows mobile devices to communicate, such as via protocols including code division multiple access (CDMA) and global system for mobile communication (GSM), with each other and with devices in the wider telecommunication network.

The first wireless access point 106 issues a domain name services (DNS) query to get identifiers for security gateways, such as the connectivity addresses for the first primary security gateway 110 and the first backup security gateway 112. Additionally, the first wireless access point 106 gets the connectivity addresses for any alternative security gateways to use if the both first primary security gateway 110 and the first backup security gateway 112 fail, or if the first call manager 114 fails. Once the first wireless access point 106 gets the connectivity addresses, the first wireless access point 106 connects to and registers with the first primary security gateway 110. In this manner, the first primary security gateway 110 gets an identifier for the first wireless access point 106. As a security measure, a security gateway enables a wireless access point to access a network only if the security gateway has an identifier for the wireless access point.

In some embodiments, the first wireless access point 106 establishes a secure tunnel using the first primary security gateway 110 to the first wireless service provider network 126. The first wireless service provider network 126 provides a private internet protocol address that is used for routing between the first wireless service provider network 126 and the first wireless access point 106. The first wireless access point 106 performs another DNS query to get the address for the first device manager 116.

The first wireless access point 106 connects to and registers with the first device manager 116. In this manner, the first device manager 116 gets an identifier for the first wireless access point 106. The first device manager 116 provides the address of the first call manager 114 to the first wireless access point 106. As a security measure, a device manager provides the address of a call manager to a wireless access point only if the device manager has an identifier for the wireless access point. Additionally, the first device manager 116 provides the address for any alternative call managers to use if the first call manager 114 fails. The first wireless access point 106 registers with the first call manager 114. In this manner, the first call manager 114 gets an identifier for the first wireless access point 106. The first call manager 114 promotes the first wireless access point 106 communicating over a network, such as a signaling system (SS7) network 128. The SS7 network 128 is a network used to set up telephone calls on the PSTN 124.

As a security measure, a call manager enables a wireless access point to communicate over a network only if the call manager has an identifier for the wireless access point. The call manager 114 can have the identifier for each wireless access point in a specific geographic region, along with the call policies for each wireless access point such as calling plan options and features, and get any identifiers from wireless access points in other geographic regions on an as-needed basis. Alternatively, the call manager 114 can have the identifier for each wireless access point in a broader geographic region and the call policies for each wireless access point.

The system 100 includes additional similar components, such as a third mobile device 130 and a fourth mobile device 132 that communicate with the internet 108 by using a second wireless access point 134. A second site 136 can include a second primary security gateway 138, a second backup security gateway 140, a second call manager 142, a second device manager 144, and a second media gateway 146. The second media gateway 146 connects the security gateways at the second site 136 to a second mobile switching center 148. The system 100 shows only one media gateway and one mobile switching center at the second site 136 for the purposes of illustration, but the system 100 may include any number of media gateways and mobile switching centers at the second site 136. The second mobile switching center 148 can connect to a second wireless service provider network 150 and to the public switch telephone network 124 via the SS7 network 128. Although described as two separate providers (the first and second wireless service providers 126 and 150), typically the first and second wireless service providers 126 and 150 would be the same telecommunications company. However in some embodiments, the first and second wireless service providers 126 and 150 might be different telecommunications companies.

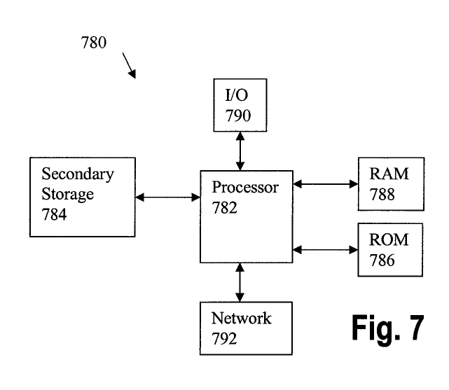

The components communicating with the second wireless access point 134 and the components at the second site 136 function in a similar manner to the components communicating with the first wireless access point 106 and the components at the first site 120. Components in the system 100, such as the security gateways, the call managers, the device managers, the media gateways, and the mobile switching centers can be implemented, for example, by a general-purpose computer system, which is described in more detail below with reference to FIG. 7.

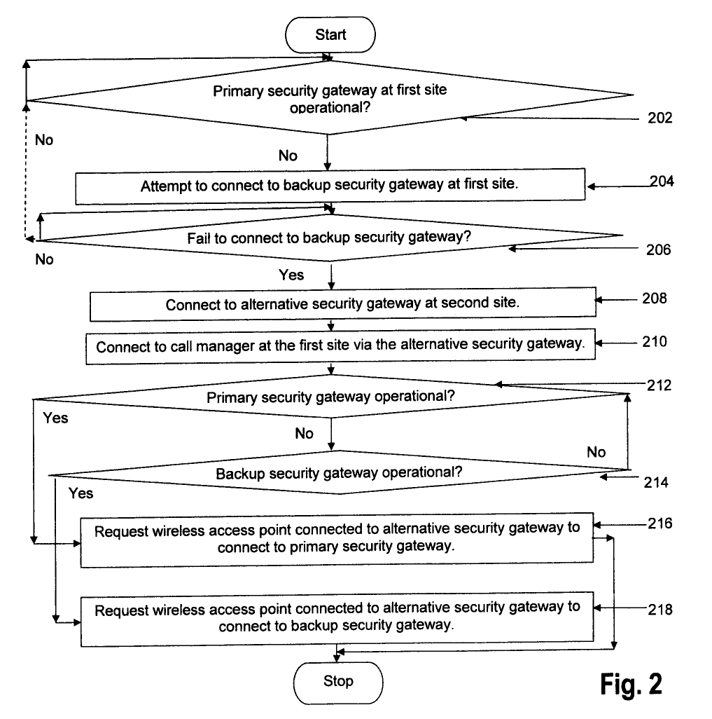

Turning now to FIG. 2, a flowchart of a method for wireless access point failover is depicted according to an embodiment of the present disclosure. Executing the method enables a wireless access point to connect to a call manager after a failure of both the primary and backup security gateways at a first site that was previously servicing the wireless access point.

In block 202, a wireless access point determines if a primary security gateway at a site has failed. For example, the first wireless access point 106 determines if the first primary security gateway 110 at the first site 120 has failed. If the first wireless access point 106 determines that the first primary security gateway 110 is not operational, the method proceeds to box 204. If the first wireless access point 106 determines that the first primary security gateway 110 is operational, the method remains in box 202 to periodically determine if the first primary security gateway 110 is not operational.

In block 204, the wireless access point attempts to connect to the backup security gateway at the same site. For example, the first wireless access point 106 attempts to connect to the first backup security gateway 112 at the first site 120. The number of times that the first wireless access point 106 attempts to connect to the first backup security gateway 112 is a configurable number.

In block 206, the wireless access point determines if it fails to connect to the backup security gateway. For example, the first wireless access point 106 determines if it fails to connect to the first backup security gateway 112 at the first site 120, such as during a disaster at the first site 120 that cause both the first primary security gateway 110 and the first backup security gateway 112 to fail. In the event of a failure of the first backup security gateway 112, the method proceeds to box 208. If the first wireless access point 106 connects to the first backup security gateway 112, the method remains in box 206 to monitor the connection between the first wireless access point 106 and the first backup security gateway 112. Alternatively, the method returns to box 202 to periodically determine if the first primary security gateway 110 has come back on line. If the connection between the first wireless access point 106 and the first backup security gateway 112 subsequently fails, and the primary security gateway 110 has not come back on line, the method proceeds to box 208.

In block 208, the wireless access point connects to the primary security gateway at another site. For example, the first wireless access point 106 connects to the second primary security gateway 138 at the second site 136 The first wireless access point 106 may have the connectivity addresses for one or more alternative security gateways because the first wireless access point 106 retrieved the connectivity addresses through a DNS query or because the first wireless access point 106 was initially configured with the connectivity addresses. Alternatively, the first wireless access point 106 may request the connectivity addresses through a DNS query or may be provided with the connectivity addresses when the original security gateways failed. Also, the second primary security gateway 138 can have the identifier for each wireless access point in a specific geographic region, and get any identifiers from wireless access points in other geographic regions on an as-needed basis, such as under emergency failure conditions. Alternatively, the second primary security gateway 138 can have the identifier for each wireless access point in a broader geographic region.

In block 210, the wireless access point connects to the call manager at the site via the alternative security gateway at the alternative site. For example, the first wireless access point 106 connects to the first call manager 114 at the first site 120 via the second primary security gateway 138 at the second site 136. Because the first wireless access point 106 was previously connected to the first call manager 114 at the first site 120, the first call manager 114 already has an identifier for the first wireless access point 106.

In block 212, the device manager determines if the security gateway is operational. For example, the first device manager 116 determines if the first primary security gateway 110 at the first site 120 is operational. The frequency at which the first device manager 116 determines if the first primary security gateway 110 is operational is configurable. If the first device manager 116 determines that the first primary security gateway 110 is operational, the method proceeds to box 216. If the first device manager 116 determines that the first primary security gateway 110 is not operational, the method proceeds to box 214 to determine if the first backup security gateway 112 is operational.

In block 214, the device manager determines if the backup security gateway is operational. For example, the first device manager 116 determines if the first backup security gateway 112 at the first site 120 is operational. If the first device manager 116 determines that the first backup security gateway 112 is operational, the method proceeds to box 218. If the first device manager 116 determines that the first backup security gateway 112 is not operational, the method returns to box 212 to determine if the first primary security gateway 110 is operational. The frequency at which the first device manager 116 determines if the first backup security gateway 112 is operational is configurable.

In block 216, the device manager requests the wireless access point connected to the alternative security gateway to connect to the original security gateway. For example, when the first primary security gateway 110 becomes operational, the first device manager 116 requests the first wireless access point 106 connected to the second primary security gateway 138 at the second site 136 to connect to the first primary security gateway 110 at the first site 120. If the first wireless access point 106 is idle, or not actively communicating through the second primary security gateway 138, the first wireless access point 106 connects to the first primary security gateway 110. By connecting when the first wireless access point 106 is idle, the first primary security gateway 110 gradually reassumes its original load without suddenly reassuming a large traffic load. If the first wireless access point 106 is not idle, or is actively communicating through the second primary security gateway 138, the first wireless access point 106 waits until it becomes idle before it connects to the first primary security gateway 110.

In box 218, the device manager requests the wireless access point connected to the alternative security gateway to connect to the original backup security gateway. For example, when the first backup security gateway 112 becomes operational, the first device manager 116 requests the first wireless access point 106 connected to the second primary security gateway 138 at the second site 136 to connect to the first backup security gateway 112 at the first site 120. If the first wireless access point 106 is idle, or not actively communicating through the second primary security gateway 138, the first wireless access point 106 connects to the first backup security gateway 112. If the first wireless access point 106 is not idle, or is actively communicating through the second primary security gateway 138, the first wireless access point 106 waits until it becomes idle before it connects to the first backup security gateway 112.

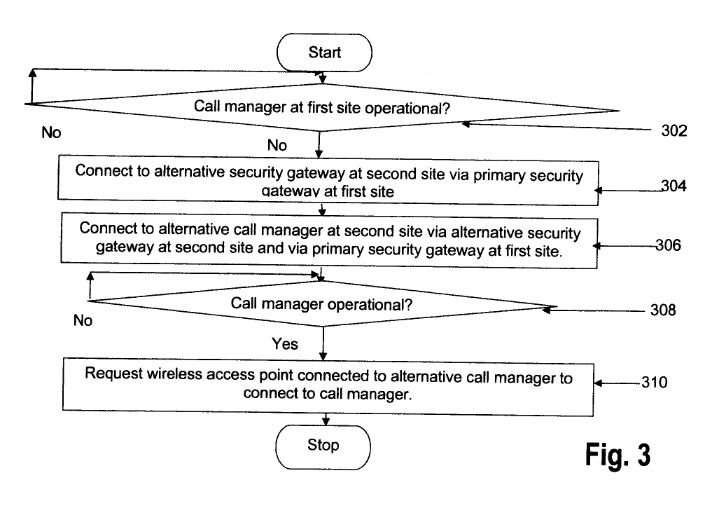

Turning now to FIG. 3, a flowchart of another method for wireless access point failover is depicted according to an embodiment of the present disclosure. Executing the method enables a wireless access point to connect to an alternative call manager after a failure of the call manager to which the wireless access point is connected.

In box 302, a wireless access point determines if a call manager at a site is not operational. For example, the first wireless access point 106 determines if the first call manager 114 at the first site 120 is not operational. If the first wireless access point 106 determines that the first call manager 114 is not operational, the method proceeds to box 304. If the first wireless access point 106 determines that the first call manager 114 is operational, the method remains in box 302 to periodically determine if the first call manager 114 is not operational.

In box 304, the wireless access point connects to an alternative security gateway at another site via the security gateway at the site. For example, the first wireless access point 106 connects to the second primary security gateway 138 at the second site 136 via the first primary security gateway 110 at the first site 120. Alternatively, the first wireless access point 106 connects directly to the second primary security gateway 138 at the second site 136 without routing via the first primary security gateway 110 at the first site 120. The first wireless access point 106 may already have the connectivity addresses for alternative security gateways, such as the second primary security gateway 138. Alternatively, the first wireless access point 106 may request the connectivity addresses through a DNS query or may be provided with the connectivity addresses when the original security gateways failed. The second primary security gateway 138 may be provided with identifiers for each wireless access point in a specific geographic region and get identifiers from wireless access points in other geographic regions on an as-needed basis, such as under emergency conditions. Alternatively, the second primary security gateway 138 can have the identifier for each wireless access point in a broader geographic region.

In box 306, the wireless access point connects to the alternative call manager at another site via the alternative security gateway at the other site and via the security gateway at the site. For example, the first wireless access point 106 connects to the second call manager 142 at the second site 136 via the second primary security gateway 136 at the second site 136 and via the first primary security gateway 110 at the first site 120. Alternatively, the first wireless access point 106 connects to the second call manager 142 at the second site 136 via the second primary security gateway 136 at the second site 136 without routing via the first primary security gateway 110 at the first site 120. The first wireless access point 106 may already have the connectivity addresses for alternative call managers, such as the second call manager 142, in cases where the first call manager 114 fails. Alternatively, the first wireless access point 106 may request the connectivity addresses through registering with the second device manager 144, or may be provided with the connectivity addresses when the first call manager 114 failed. The second call manager 142 can have the identifier for each wireless access point in a specific geographic region, along with the call policies for these wireless access points, and get identifiers from wireless access points in other geographic regions on an as-needed basis, such as in emergencies. Alternatively, the second call manager 142 can have the identifier for each wireless access point in a broader geographic region and the call policies for these wireless access points.

In box 308, the device manager determines if the call manager is operational. For example, the first device manager 116 determines if the first call manager 114 at the first site 120 is operational. If the first wireless access point 106 determines that the first call manager 114 is operational, the method proceeds to box 310. If the first wireless access point 106 determines that the first call manager 114 is not operational, the method remains in box 308 to periodically determine if the first call manager 114 is operational.

In box 310, the device manager requests the wireless access point connected to the alternative call manager to connect to the call manager. For example, the first device manager 116 requests the first wireless access point 106 connected to the second call manager 142 at the second site 136 to connect to the first call manager 114 at the first site 120. If the first wireless access point 106 is idle, or not actively communicating with the second call manager 142, the first wireless access point 106 connects to the first call manager 114. By connecting when the first wireless access point 106 is idle, the first call manager 114 gradually reassumes its original load without suddenly reassuming a large traffic load. If the first wireless access point 106 is not idle, or actively communicating with the second call manager 142, the first wireless access point 106 waits until it becomes idle before it connects to the first call manager 114.

If a wireless access point determines that a primary security gateway, a backup security gateway, and a call manager at a site have all failed, both of the methods depicted in FIG. 2 and FIG. 3 can be executed to enable the wireless access point to connect to an alternative call manager via an alternative security gateway at an alternative site. For example, if the first wireless access point 106 determines that the first primary security gateway 110, the first backup security gateway 112, and the first call manager 114 at the first site 120 have all failed, the first wireless access point 106 can connect to the second call manager 142 via the second primary security gateway 138 at the second site 136. Similarly, the device manager determines on an individual basis if the call manager and the security gateways that failed are operational, and requests the wireless access point to reconnect to the call manager or security gateway that is now operational when the wireless access point becomes idle.

FIG. 4 shows a wireless communications system including the mobile device 102. FIG. 4 depicts the mobile device 102, which is operable for implementing aspects of the present disclosure, but the present disclosure should not be limited to these implementations. Though illustrated as a mobile phone, the mobile device 102 may take various forms including a dual mode handset, a wireless mobile device, a pager, a personal digital assistant (PDA), a portable computer, a tablet computer, a laptop computer, a digital camera, a digital music player, a digital calculator, and an electronic key fob for keyless entry. Many suitable mobile devices combine some or all of these functions.

The mobile device 102 includes a display 402 and a touch-sensitive surface or keys 404 for input by a user. The mobile device 102 may present options for the user to select, controls for the user to actuate, and/or cursors or other indicators for the user to direct, including options such as telephone numbers to dial. The mobile device 102 may further accept data entry from the user, including numbers to dial or various parameter values for configuring the operation of the mobile device. The mobile device 102 may further execute one or more software or firmware applications in response to user commands. These applications may configure the mobile device 102 to perform various customized functions in response to user interaction.

Among the various applications executable by the mobile device 102 are a web browser, which enables the display 402 to show a web page. The web page is obtained via wireless communications with a cell tower 406, a wireless network access node, such as the first wireless access point 106, or another wireless communications network or system. The cell tower 406 (or wireless network access node) is coupled to a wired network 408, such as the internet 108. Via the wireless link and the wired network, the mobile device 102 has access to information on various servers, such as a content server 410. The content server 410 may provide content that may be shown on the display 402.

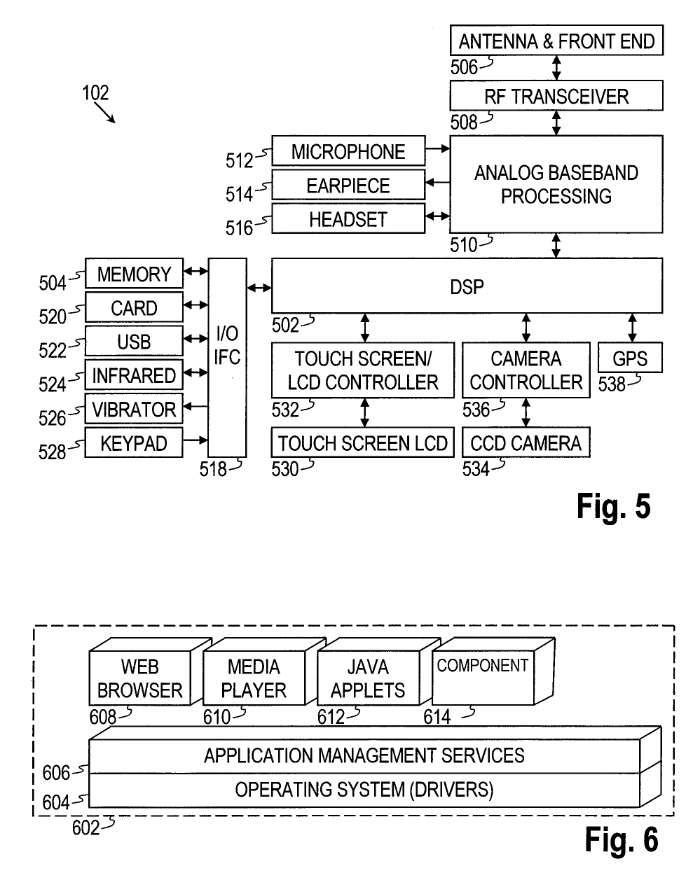

FIG. 5 shows a block diagram of the mobile device 102. The mobile device 102 includes a digital signal processor (DSP) 502 and a memory 504. As shown, the mobile device 102 may further include an antenna and front end unit 506, a radio frequency (RF) transceiver 508, an analog baseband processing unit 510, a microphone 512, an earpiece speaker 514, a headset port 516, an input/output interface 518, a removable memory card 520, a universal serial bus (USB) port 522, an infrared port 524, a vibrator 526, a keypad 528, a touch screen liquid crystal display (LCD) with a touch sensitive surface 530, a touch screen/LCD controller 532, a charge-coupled device (CCD) camera 534, a camera controller 536, and a global positioning system (GPS) sensor 538.

The DSP 502 or some other form of controller or central processing unit operates to control the various components of the mobile device 102 in accordance with embedded software or firmware stored in memory 504. In addition to the embedded software or firmware, the DSP 502 may execute other applications stored in the memory 504 or made available via information carrier media such as portable data storage media like the removable memory card 520 or via wired or wireless network communications. The application software may comprise a compiled set of machine-readable instructions that configure the DSP 502 to provide the desired functionality, or the application software may be high-level software instructions to be processed by an interpreter or compiler to indirectly configure the DSP 502.

The antenna and front end unit 506 may be provided to convert between wireless signals and electrical signals, enabling the mobile device 102 to send and receive information from a cellular network or some other available wireless communications network. The RF transceiver 508 provides frequency shifting, converting received RF signals to baseband and converting baseband transmit signals to RF. The analog baseband processing unit 510 may provide channel equalization and signal demodulation to extract information from received signals, may modulate information to create transmit signals, and may provide analog filtering for audio signals. To that end, the analog baseband processing unit 510 may have ports for connecting to the built-in microphone 512 and the earpiece speaker 514 that enable the mobile device 102 to be used as a cell phone. The analog baseband processing unit 510 may further include a port for connecting to a headset or other hands-free microphone and speaker configuration.

The DSP 502 may send and receive digital communications with a wireless network via the analog baseband processing unit 510. In some embodiments, these digital communications may provide Internet connectivity, enabling a user to gain access to content on the Internet 108 and to send and receive e-mail or text messages. The input/output interface 518 interconnects the DSP 502 and various memories and interfaces. The memory 504 and the removable memory card 520 may provide software and data to configure the operation of the DSP 502. Among the interfaces may be the USB interface 522 and the infrared port 524. The USB interface 522 may enable the mobile device 102 to function as a peripheral device to exchange information with a personal computer or other computer system. The infrared port 524 and other optional ports such as a Bluetooth interface or an IEEE 802.11 compliant wireless interface may enable the mobile device 102 to communicate wirelessly with other nearby mobile devices and/or wireless base stations, such as the first wireless access point 106.

The input/output interface 518 may further connect the DSP 502 to the vibrator 526 that, when triggered, causes the mobile device 102 to vibrate. The vibrator 526 may serve as a mechanism for silently alerting the user to any of various events such as an incoming call, a new text message, and an appointment reminder.

The keypad 528 couples to the DSP 502 via the interface 518 to provide one mechanism for the user to make selections, enter information, and otherwise provide input to the mobile device 102, including information entered such as telephone numbers to dial. Another input mechanism may be the touch screen LCD 530, which may also display text and/or graphics to the user. The touch screen LCD controller 532 couples the DSP 502 to the touch screen LCD 530.

The CCD camera 534 enables the mobile device 102 to take digital pictures. The DSP 502 communicates with the CCD camera 534 via the camera controller 536. The GPS sensor 538 is coupled to the DSP 502 to decode global positioning system signals, thereby enabling the mobile device 102 to determine its position. Various other peripherals may also be included to provide additional functions, e.g., radio and television reception.

FIG. 6 illustrates a software environment 602 that may be implemented by the DSP 502. The DSP 502 executes operating system drivers 604 that provide a platform from which the rest of the software operates. The operating system drivers 604 provide drivers for the mobile device hardware with standardized interfaces that are accessible to application software. The operating system drivers 604 include application management services (“AMS”) 606 that transfer control between applications running on the mobile device 102. Also shown in FIG. 6 are a web browser application 608, a media player application 610, Java applets 612, and a component 614. The web browser application 608 configures the mobile device 102 to operate as a web browser, allowing a user to enter information into forms and select links to retrieve and view web pages. The media player application 610 configures the mobile device 102 to retrieve and play audio or audiovisual media. The Java applets 612 configure the mobile device 102 to provide games, utilities, and other functionality. The component 614 is configured to promote operation in accordance with disclosed embodiments.

The system 100 described above may be implemented on any general-purpose computer with sufficient processing power, memory resources, and network throughput capability to handle the necessary workload placed upon it. FIG. 7 illustrates a typical, general-purpose computer system suitable for implementing one or more embodiments disclosed herein. The computer system 780 includes a processor 782 (which may be referred to as a central processor unit or CPU) that is in communication with memory devices including secondary storage 784, read only memory (ROM) 786, random access memory (RAM) 788, input/output (I/O) 790 devices, and network connectivity devices 792. The processor may be implemented as one or more CPU chips.

The secondary storage 784 is typically comprised of one or more disk drives or tape drives and is used for non-volatile storage of data and as an over-flow data storage device if the RAM 788 is not large enough to hold all working data. The secondary storage 784 may be used to store programs that are loaded into the RAM 788 when such programs are selected for execution. The ROM 786 is used to store instructions and perhaps data that are read during program execution. The ROM 786 is a non-volatile memory device that typically has a small memory capacity relative to the larger memory capacity of secondary storage. The RAM 788 is used to store volatile data and perhaps to store instructions. Access to both the ROM 786 and the RAM 788 is typically faster than to the secondary storage 784.

The I/O 790 devices may include printers, video monitors, liquid crystal displays (LCDs), touch screen displays, keyboards, keypads, switches, dials, mice, track balls, voice recognizers, card readers, paper tape readers, or other well-known input devices. The network connectivity devices 792 may take the form of modems, modem banks, ethernet cards, universal serial bus (USB) interface cards, serial interfaces, token ring cards, fiber distributed data interface (FDDI) cards, wireless local area network (WLAN) cards, radio transceiver cards such as code division multiple access (CDMA) and/or global system for mobile communications (GSM) radio transceiver cards, and other well-known network devices. These network connectivity 792 devices may enable the processor 782 to communicate with an Internet or one or more intranets. With such a network connection, it is contemplated that the processor 782 might receive information from the network, or might output information to the network in the course of performing the above-described method steps, including information such as registering to communicate with the first wireless access point 106. Such information, which is often represented as a sequence of instructions to be executed using the processor 782, may be received from and outputted to the network, for example, in the form of a computer data signal embodied in a carrier wave.

Such information, which may include data or instructions to be executed using the processor 782 for example, may be received from and outputted to the network, for example, in the form of a computer data baseband signal or signal embodied in a carrier wave. The baseband signal or signal embodied in the carrier wave generated by the network connectivity 792 devices may propagate in or on the surface of electrical conductors, in coaxial cables, in waveguides, in optical media, for example optical fiber, or in the air or free space. The information contained in the baseband signal or signal embedded in the carrier wave may be ordered according to different sequences, as may be desirable for either processing or generating the information or transmitting or receiving the information. The baseband signal or signal embedded in the carrier wave, or other types of signals currently used or hereafter developed, referred to herein as the transmission medium, may be generated according to several methods well known to one skilled in the art.

The processor 782 executes instructions, codes, computer programs, scripts that it accesses from hard disk, floppy disk, optical disk (these various disk based systems may all be considered the secondary storage 784), the ROM 786, the RAM 788, or the network connectivity devices 792.

While several embodiments have been provided in the present disclosure, it should be understood that the disclosed systems and methods may be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

Also, techniques, systems, subsystems and methods described and illustrated in the various embodiments as discrete or separate may be combined or integrated with other systems, modules, techniques, or methods without departing from the scope of the present disclosure. Other items shown or discussed as coupled or directly coupled or communicating with each other may be indirectly coupled or communicating through some interface, device, or intermediate component whether electrically, mechanically, or otherwise. Other examples of changes, substitutions, and alterations are ascertainable by one skilled in the art and could be made without departing from the spirit and scope disclosed herein.

What is claimed is:

1. A system for wireless access point failover, comprising:
a primary security gateway at a first site a backup security gateway at the first site;
a call manager at the first site an alternative security gateway at a second site;
a mobile device; and
a wireless access point for the mobile device to attempt to connect to the backup security gateway at the first site in response to determining that the primary security gateway at the first site is not operational, the wireless access point configured to connect to the alternative security gateway at the second site in response to failing to connect to the backup security gateway and to connect to the call manager via the alternative security gateway.

2. The system of claim 1, further comprising:
an alternative call manager at the second site;
wherein the wireless access point is further operable to connect to the alternative call manager at the second site via the alternative security gateway at the second site in response to determining that the call manager at the first site is not operational.

3. The system of claim 1, further comprising a device manager to determine if the primary security gateway is operational, and to request the wireless access point connected to the alternative security gateway to connect to the primary security gateway in response to determining that the primary security gateway is operational, such that the wireless access point connects to the primary security gateway when the wireless access point is idle in response to the request.

4. The system of claim 2, further comprising a device manager to determine if the call manager is operational, and to request the wireless access point connected to the alternative call manager to connect to the call manager in response to determining that the call manager is operational, such that the wireless access point connects to the call manager when the wireless access point is idle in response to the request.

5. The system of claim 2, further comprising a device manager to determine if the call manager is not operational, and to request the wireless access point connected to the call manager to connect to the alternative call manager in response to determining that the call manager is not operational, such that the wireless access point connects to the alternative call manager when the wireless access point is idle in response to the request.

6. The system of claim 1 wherein each of the primary security gateway, the backup security gateway, and the alternative security gateway include an identifier for the wireless access point, and the wireless access point includes an identifier for each of the primary security gateway, the backup security gateway, and the alternative security gateway.

7. The system of claim 2 wherein each of the call manager and the alternative call manager include an identifier for the wireless access point, and the wireless access point includes an identifier for each of the call manager and the alternative call manager.

8. The system of claim 1, further comprising a device manager to determine if the backup security gateway is operational, and to request the wireless access point connected to the alternative security gateway to connect to the backup security gateway in response to determining that the backup security gateway is operational, such that the wireless access point connects to the backup security gateway when the wireless access point is idle in response to the request.

9. A method for wireless access point failover, comprising:
attempting to connect to a backup security gateway at a first site in response to determining that a primary security gateway at the first site is not operational;
connecting to an alternative security gateway at a second site in response to failing to connect to the backup security gateway at the first site; and
connecting to a call manager at the first site via the alternative security gateway at the second site.

10. The method of claim 9, further comprising:
connecting to an alternative call manager at the second site via the alternative security gateway at the second site in response to determining that the call manager at the first site is not operational.

11. The method of claim 9, further comprising:
determining if the primary security gateway is operational; and
requesting the wireless access point connected to the alternative security gateway to connect to the primary security gateway in response to determining that the primary security gateway is operational, such that the wireless access point connects to the primary security gateway when the wireless access point is idle in response to the request.

12. The method of claim 10, further comprising:
determining that the call manager is operational; and
requesting the wireless access point connected to the alternative call manager to connect to the call manager in response to determining that the call manager is operational, such that the wireless access point connects to the call manager when the wireless access point is idle in response to the request.

13. The method of claim 9 wherein each of the primary security gateway, the backup security gateway, and the alternative security gateway include an identifier for the wireless access point, and the wireless access point includes an identifier for each of the primary security gateway, the backup security gateway, and the alternative security gateway.

14. The method of claim 10 wherein each of the call manager and the alternative call manager include an identifier for the wireless access point, and the wireless access point includes an identifier for each of the call manager and the alternative call manager.

15. A system for wireless access point failover, comprising:
a call manager at a first site;
a primary security gateway at the first site;
an alternative security gateway at a second site;
an alternative call manager at the second site;
a mobile device; and
a wireless access point for the mobile device to connect to the alternative security gateway at the second site via the primary security gateway at the first site in response to determining that the call manager at the first site is not operational, and to connect to the alternative call manager at the second site via the alternative security gateway at the second site and via the primary security gateway at the first site.

16. The system of claim 15, further comprising:
a backup security gateway at the first site,
wherein the wireless access point is further operable to attempt to connect to the backup security gateway at the first site in response to determining that the primary security gateway is not operational at the first site, to connect to the alternative security gateway at the second site in response to failing to connect to the backup security gateway at the first site, and to connect to the alternative call manager at the second site via the alternative security gateway at the second site.

17. The system of claim 16, further comprising a device manager operable to determine if the primary security gateway is operational, and to request the wireless access point connected to the alternative security gateway to connect to the primary security gateway in response to determining that the primary security gateway is operational, such that the wireless access point connects to the primary security gateway when the wireless access point is idle in response to the request.

18. The system of claim 15, further comprising a device manager operable to determine that the call manager is operational, and to request the wireless access point connected to the alternative call manager to connect to the call manager in response to determining that the call manager is operational, such that the wireless access point connects to the call manager when the wireless access point is idle in response to the request.

19. The system of claim 16 wherein each of the primary security gateway, the backup security gateway, and the alternative security gateway include an identifier for the wireless access point, and the wireless access point includes an identifier for each of the primary security gateway, the backup security gateway, and the alternative security gateway.

20. The system of claim 15 wherein each of the call manager and the alternative call manager include an identifier for the wireless access point, and the wireless access point includes an identifier for each of the call manager and the alternative call manager.
